(19) United States
(12) Patent Application Publication
(10) Pub. No.: US 2025/0280686 A1
(43) Pub. Date: Sep. 4, 2025

(54) DISPLAY DEVICE

(71) Applicant: LG Display Co., Ltd., Seoul (KR)

(72) Inventors: Ji Young AHN, Paju-si (KR); Jun ho NAM, Paju-si (KR); Ahn Ki KIM, Paju-si (KR)

(21) Appl. No.: 18/774,622

(22) Filed: Jul. 16, 2024

(30) Foreign Application Priority Data
Feb. 29, 2024 (KR) 10-2024-0030215

(51) Int. Cl. H10K 59/35; H10K 59/38; H10K 59/80; H10K 102/10

(52) U.S. Cl. CPC H10K 59/351; H10K 59/38; H10K 59/80517; H10K 2102/101

(57) ABSTRACT

The present disclosure relates to a display device. A display device is provided. The display device includes a first sub-pixel emitting a light of a first color different from a light emitted by the second sub-pixel, and a second sub-pixel emitting white light. A structure of a first electrode of the first sub-pixel and a structure of a first electrode of the second sub-pixel are different. In addition, the display device includes a second electrode including a first conductive layer and a second conductive layer. A transmittance of the second conductive layer is different from a transmittance of the first conductive layer.

### CROSS-REFERENCE TO RELATED APPLICATIONS

This application claims the priority and benefit of the Korean Patent Application No. 10-2024-0030215 filed on Feb. 29, 2024, which is hereby incorporated by reference as if fully set forth herein.

### BACKGROUND

### Technical Field

The present disclosure relates to a display device, and more particularly, for example, without limitation, to a display device including high efficiency and low reflection electrode structure.

### Description of the Related Art

The display device is widely used as a display screen of a notebook computer, a tablet computer, a smart phone, a portable display device, and a portable information device in addition to a display screen of a television or a monitor. With the advancement of technology, a display device may provide photographing or various sensing functions in addition to an image display function. Accordingly, the display device may include an electronic device such as a camera or a sensor.

Among the display devices, an organic light emitting display device is a self-emission type, and has advantages such as superior viewing angle and contrast ratio compared to a liquid crystal display (LCD), light weight and thinness are possible because no separate backlight is required, and power consumption is advantageous. In addition, the organic light emitting display device has an advantage of being able to drive DC low voltage, fast response speed, and especially low manufacturing cost.

### BRIEF SUMMARY

Recently, in order to improve the light efficiency of the display device, an electrode including a highly reflective material is used. For example, in a top emission type display device, an anode of the light emitting device may be formed of the highly reflective material. In this case, when the light generated by the light emitting layer of the light emitting device proceeds toward a lower portion of the display device, the light is reflected by the anode, and a path of the light may be changed from a direction of the lower portion of the display device to a direction of the upper portion of the display device. Accordingly, a light efficiency of the display device may be improved. However, the inventors of the present disclosure have appreciated that the electrode including the highly reflective material reflects external light, and a reflectance of the display device with respect to the external light may increase. Accordingly, the inventors identified that there is a technical problem that the visibility of the display device is reduced.

The description provided in the discussion of the related art section should not be assumed to be prior art merely because it is mentioned in or associated with that section. The discussion of the related art section may include information that describes one or more aspects of the subject technology, and the description in this section does not limit the invention.

Therefore, the inventors of the present disclosure recognized the limitations or problems mentioned above and other limitations associated with the related art, and conducted various experiments to implement a display device that includes high efficiency and low reflection electrode structure.

The present disclosure has been made in view of one or more technical problems in the related art also including the above-identified problems and various embodiments of the present disclosure provide a display device including high efficiency and low reflection electrode structure.

In accordance with an aspect of the present disclosure, the above and other objects can be accomplished by the provision of a display device comprising a substrate on which a first sub-pixel and a second sub-pixel are disposed, each of the first sub-pixel and the second sub-pixel including an emitting area and a non-emitting area surrounding the emitting area, wherein each of the first and second sub-pixels includes a first electrode disposed in the emitting area, a light emitting layer disposed on the first electrode, and a second electrode disposed on the light emitting layer, the first sub-pixel emits a light of a first color different from a light emitted by the second sub-pixel, the second sub-pixel emits white light, a structure of the first electrode of the first sub-pixel and a structure of the first electrode of the second sub-pixel are different.

In addition, in accordance with an aspect of the present disclosure, the above and other objects can be accomplished by the provision of a display device comprising a substrate on which a plurality of sub-pixels are disposed, the plurality of sub-pixels including an emitting area and a non-emitting area surrounding the emitting area, wherein each of the plurality of sub-pixels includes a first electrode disposed in the emitting area, a light emitting layer disposed on the first electrode, and a second electrode disposed on the light emitting layer, the second electrode includes a first conductive layer and a second conductive layer disposed on the first conductive layer, and a transmittance of the second conductive layer is different from a transmittance of the first conductive layer.

The effects according to the present disclosure are not limited to the contents exemplified above, and more various effects are included in the present disclosure.

It is to be understood that both the foregoing general description and the following detailed description of the present disclosure are exemplary and explanatory and are intended to provide further explanation of the inventive concepts as claimed.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure.

FIG. 2 is a plan view of one pixel according to an exemplary embodiment of the present disclosure.

FIG. 3 is a cross-sectional view of a sub-pixel according to an exemplary embodiment of the present disclosure.

FIG. 4 is a cross-sectional view of a pixel according to a first exemplary embodiment of the present disclosure.

FIG. 5 is a cross-sectional view of a pixel according to a second exemplary embodiment of the present disclosure.

FIG. 6 is a cross-sectional view of a pixel according to a third exemplary embodiment of the present disclosure.

FIG. 7 is a cross-sectional view of a pixel according to a fourth exemplary embodiment of the present disclosure.

FIGS. 8A to 8D are plan views of a sub-pixel according to various exemplary embodiments.

FIG. 9 is a cross-sectional view of a sub-pixel according to another exemplary embodiment of the present disclosure.

FIG. 10 is a cross-sectional view of a pixel according to a fifth exemplary embodiment of the present disclosure.

FIG. 11 is a cross-sectional view of a pixel according to a sixth exemplary embodiment of the present disclosure.

FIG. 12 is a cross-sectional view of a pixel according to a seventh exemplary embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Advantages and features of the present disclosure and implementation methods thereof will be clarified through following exemplary embodiments described with reference to the accompanying drawings. The present disclosure may, however, be embodied in different forms and should not be construed as limited to the exemplary embodiments set forth herein. Rather, these exemplary embodiments are provided so that this disclosure will be sufficiently thorough and complete and will fully convey the scope of the present disclosure to those skilled in the art. Further, the present disclosure is only defined by scopes of claims.

A shape, a size, a dimension (e.g., length, width, height, thickness, radius, diameter, area, etc.), a ratio, an angle, a number, and the like disclosed in the drawings for describing exemplary embodiments of the present disclosure are merely an example and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the aspects of the present disclosure, the detailed description will be omitted. In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description. Any implementation described herein as an “example” is not necessarily to be construed as preferred or advantageous over other implementations.

In describing a position relationship, for example, when the position relationship is described as ‘upon˜,’ ‘above˜,’ ‘below˜’, “beside˜”, ‘next to˜,’ or the like one or more portions may be disposed between two other portions unless ‘just’ or ‘direct’ is used, that is, one or more other parts may be disposed located between the two parts. For example, where an element or layer is disposed “on” another element or layer, a third layer or clement may be interposed therebetween. The terms, such as “below,” “lower,” “above,” “upper” and the like, may be used herein to describe a relationship between element(s) as illustrated in the drawings. It will be understood that the terms are spatially relative and based on the orientation depicted in the drawings.

It will be understood that, although the terms “first,” “second,” “A,” “B,” “(a),” and “(b),” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various exemplary embodiments of the present disclosure may be partially or overall coupled to or combined with each other and may be variously inter-operated with each other and driven technically as those skilled in the art can sufficiently understand. The exemplary embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which exemplary example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, example embodiments of the present disclosure will be described in detail with reference to the accompanying drawings. For convenience of description, a scale of each of elements illustrated in the accompanying drawings differs from a real scale, and thus, is not limited to a scale illustrated in the drawings

Hereinafter, the preferred exemplary embodiment of the present disclosure will be described in detail with reference to the accompanying drawings.

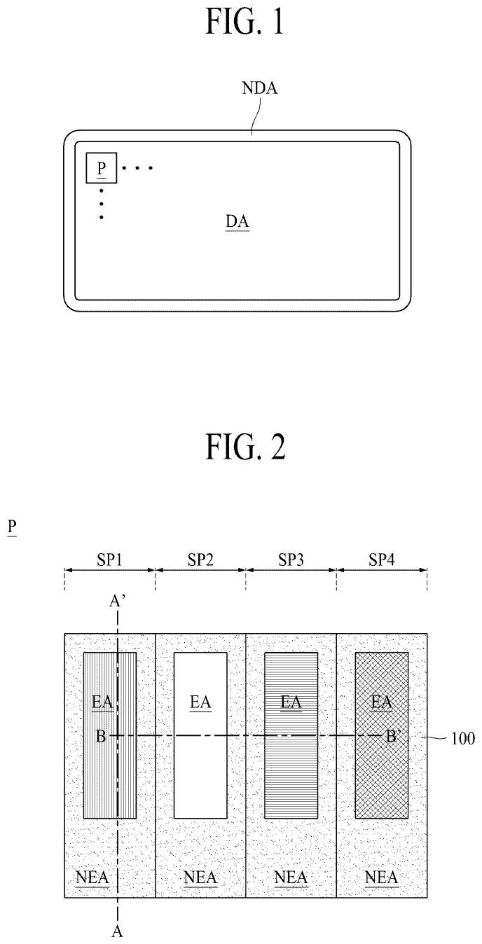

FIG. 1 is a plan view of a display device according to an exemplary embodiment of the present disclosure.

Referring to FIG. 1, a display device according to an exemplary embodiment of the present disclosure may include a display area DA and a non-display area NDA surrounding the display area DA. The display area DA is an area in which an image may be displayed, and the non-display area NDA is an area in which an image is not displayed.

The display area DA may include a plurality of pixels P. The plurality of pixels P may be arranged in a matrix form consisting of a plurality of rows and columns. Also, the non-display area NDA may include a plurality of wirings, pads, driving circuits, and the like for driving the plurality of pixels P. However, the configurations of the display area DA and the non-display area NDA are not limited thereto.

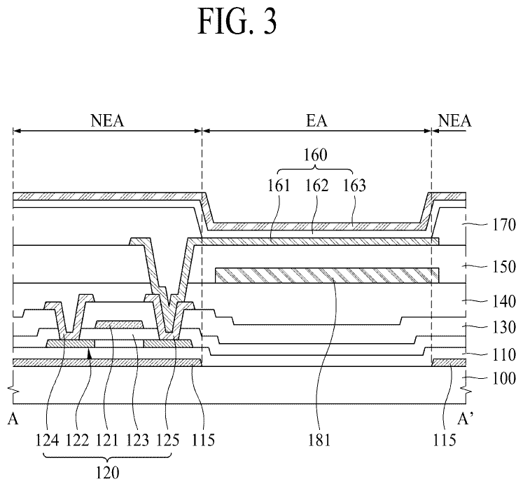

FIG. 2 is a plan view of one-pixel P according to an exemplary embodiment of the present disclosure.

Referring to FIG. 2, one-pixel P may include a plurality of sub-pixels, such as a first sub-pixel, a second sub-pixel, a third sub-pixel and a fourth sub-pixel SP1, SP2, SP3 and SP4, but is not limited thereto. The plurality of sub-pixels, such as first to fourth sub-pixels SP1 to SP4 may emit light different from each other such as red, green, or blue (e.g., white, red, green, or blue, or cyan, magenta, or yellow, etc.). For example, the first sub-pixel SP1 may emit a light of a first color, such as red light, the second sub-pixel SP2 may emit a light of a second color, such as white light, the third sub-pixel SP3 may emit a light of a third color, such as blue light, and the fourth sub-pixel SP4 may emit a light of a fourth color, such as green light, but is not limited thereto. Also, although FIG. 2 shows that one-pixel P includes four sub-pixels SP1 to SP4, the one-pixel P is not limited thereto, and one-pixel P may include fewer or more sub-pixels.

Each of the first to fourth sub-pixels SP1 to SP4 is disposed on the substrate 100 and may include an emitting area EA and a non-emitting area NEA surrounding the emitting area EA. The emitting area EA is an area capable of emitting light, and the non-emitting area NEA is an area that does not emit light. Also, a light emitting element may be disposed in the emitting area EA, and a bank may be disposed in the non-emitting area NEA.

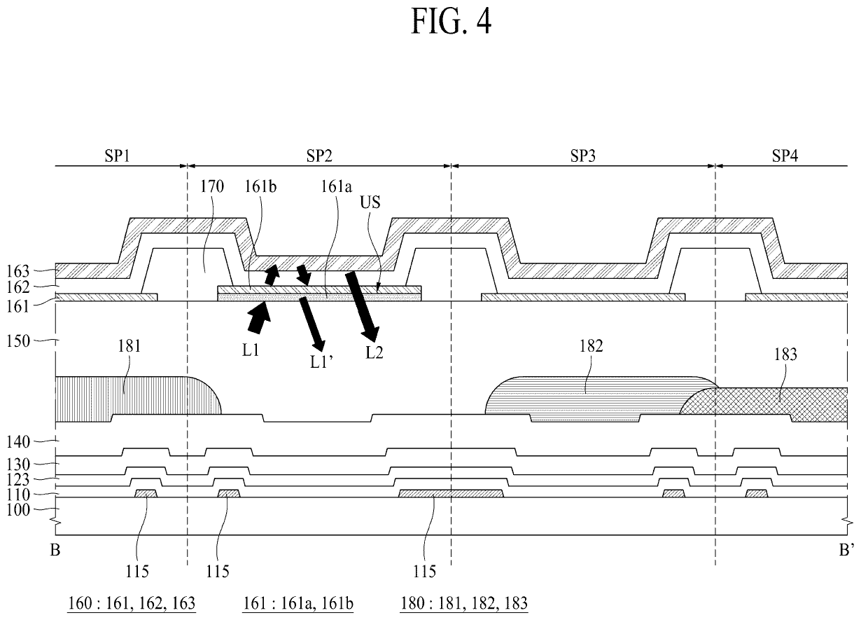

FIG. 3 is a cross-sectional view of a sub-pixel SP according to an exemplary embodiment of the present disclosure. In detail, FIG. 3 is a cross-sectional view of the first sub-pixel SP1 taken along line A-A′ of FIG. 2.

Referring to FIG. 3, one sub-pixel SP according to an exemplary embodiment of the present disclosure may include a substrate 100, a buffer layer 110, a light blocking layer 115, a thin film transistor 120, a passivation layer 130, a first planarization layer 140, a second planarization layer 150, a light emitting device 160, a bank 170, and a first color filter 181 and the like, but the present disclosure is not limited thereto.

The substrate 100 may be made of glass, plastic, or a flexible polymer film, but is not limited thereto. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto. The display device according to an exemplary embodiment of the present disclosure may be made of a bottom emission type in which the emitted light is emitted downward. Therefore, a transparent material may be used as the material of the substrate 100.

The light blocking layer 115 may be disposed on the substrate 100. The light blocking layer 115 may be disposed in an area overlapping the thin film transistor 120 and the bank 170. The light blocking layer 115 may prevent or reduce external light from penetrating into a channel area of the thin film transistor 120. Also, the light blocking layer 115 may prevent or reduce light from penetrating into the non-emitting area NEA. The light blocking layer 115 may include an opaque metal material such as molybdenum (Mo), but is not limited thereto.

The buffer layer 110 may be disposed on the substrate 100 and the light blocking layer 115. The buffer layer 110 may cover the light blocking layer 115 and compensate for a step difference caused by the light blocking layer 115. Also, adhesion between the thin film transistor 120 and the substrate 100 may be improved. The buffer layer 110 may be formed of an inorganic insulating material, such as silicon oxide (SiOx), silicon nitride (SiNx), silicon oxynitride (SiOxNy), or the like, but is not limited thereto.

The thin film transistor 120 may be disposed on the buffer layer 110 and may be disposed in the non-emission area NEA. Also, the thin film transistor 120 may be disposed in an area overlapping the light blocking layer 115. The thin film transistor 120 may include a gate electrode 121, a semiconductor layer 122, a gate insulating layer 123, a first electrode such as a source electrode 124, a second electrode such as a drain electrode 125, and the like, but the present disclosure is not limited thereto.

The semiconductor layer 122 of the thin film transistor 120 may be disposed on the buffer layer 110. Also, the gate electrode 121 may be disposed on the semiconductor layer 122. The semiconductor layer 122 may include a poly-silicon semiconductor or an oxide semiconductor. In addition, when the semiconductor layer 122 includes an oxide semiconductor, at least one oxide of indium-gallium-zinc-oxide (IGZO), indium-zinc-oxide (IZO), indium-gallium-tin-oxide (IGTO), and indium-gallium-oxide (IGO) may be included. Also, the gate electrode 121 may be formed of a conductive material, for example, copper Cu, aluminum Al, molybdenum Mo, nickel Ni, titanium Ti, chromium Cr, or an alloy thereof, but is not limited thereto.

To insulate the gate electrode 121 from the semiconductor layer 122, a gate insulating layer 123 may be disposed between the gate electrode 121 and the semiconductor layer 122. The gate insulating layer 123 may include a single layer of silicon nitride (SiNx) or silicon oxide (SiOx), or multiple layers thereof. Also, although FIG. 3 shows a top gate structure in which the gate electrode 121 is disposed on the semiconductor layer 122, it is not limited thereto. For example, a bottom gate structure in which the semiconductor layer 122 is disposed on the gate electrode 121 may be disclosed.

The passivation layer 130 may be disposed on the gate electrode 121. The passivation layer 130 may be formed of an inorganic insulating material such as silicon oxide (SiOx), silicon nitride (SiNx), silicon oxynitride (SiOxNy), or the like. Depending on circumstances, the passivation layer 130 may be omitted when the first planarization layer 140 has a function of protecting the thin film transistor 120. The source electrode 124 and the drain electrode 125 may be disposed on the passivation layer 130 while facing each other. The source electrode 124 and the drain electrode 125 may be connected with the semiconductor layer 122 through contact holes formed in the gate insulating layer 123 and the passivation layer 130.

The first and second planarization layers 140 and 150 may be disposed on the thin film transistor 120. The first planarization layer 140 may be disposed on the thin film transistor 120, and the second planarization layer 150 may be disposed on the first planarization layer 140. The first and second planarization layers 140 and 150 may protect the thin film transistor 120. The first and second planarization layers 140 and 150 may compensate for a step difference caused by the thin film transistor 120 to planarize an upper region of the thin film transistor 120. Furthermore, the first and second planarization layers 140 and 150 may be formed of an organic insulating material such as an acrylic resin, an epoxy resin, a phenolic resin, a polyimide resin, or a polyimide resin, but embodiments are not limited thereto.

The light emitting device 160 may be disposed on the second planarization layer 150. The light emitting device 160 may include a first electrode 161, a light emitting layer 162, and a second electrode 163, but is not limited thereto.

The first electrode 161 may be disposed on the second planarization layer 150 and may function as an anode of the display device. The first electrode 161 may be electrically connected with the drain electrode 125 of the thin film transistor 120 through a contact hole formed in the first and second planarization layers 140 and 150, but is not limited thereto.

Since the display device according to an exemplary embodiment of the present disclosure is configured in a bottom emission type, the first electrode 161 may include a transparent conductive material such as an indium tin oxide (ITO) or an indium zinc oxide (IZO) to transmit the light emitted from the light emitting layer 162 to a lower side of the display device. Also, the display device according to an exemplary embodiment of the present disclosure may be configured in a top emission type.

The bank 170 may be disposed on the second planarization layer 150 and the first electrode 161. The bank 170 serves to define a sub-pixel. The bank 170 may define an emitting area EA and a non-emitting area NEA. That is, the area in which the bank 170 is not disposed may become the emitting area EA, and the area in which the bank 170 is disposed may become the non-emitting area NEA.

The bank 170 may include an organic insulating material such as an acrylic resin, an epoxy resin, a phenolic resin, a polyamide resin, a polyimide resin, or the like. Alternatively, the bank 170 may include an inorganic insulating material such as silicon oxide (SiOx), silicon nitride (SiNx), silicon oxynitride (SiOxNy). Also, the bank 170 may include a black dye in order to absorb light incident from the outside. Further, the bank 170 may also be made of a transparent insulating material.

The light emitting layer 162 may be disposed on the first electrode 161. The light emitting layer 162 may also be disposed on an upper surface of the bank 170. The light emitting layer 162 may include one or more of a hole transporting layer, an organic light emission layer, an electron transporting layer, but the present disclosure is not limited thereto. In this case, when a voltage is applied to the first electrode 161 and the second electrode 163, holes and electrons move to the organic light emission layer through the hole transport layer and the electron transport layer, respectively, and may be combined with each other in the organic light emission layer to emit light.

The second electrode 163 may be disposed on the light emitting layer 162. The second electrode 163 may function as a cathode of the display device, but is not limited thereto. Like the light emitting layer 162, the second electrode 163 may also be disposed on the upper surface of the bank 170.

The second electrode 163 may be made of a highly reflective metal material. For example, the second electrode 163 may include a metal material such as aluminum (Al), silver (Ag), copper (Cu), molybdenum (Mo), titanium (Ti), tungsten (W), or chromium (Cr), or an alloy thereof. Also, the second electrode 163 may include a transparent conductive material such as an indium tin oxide (ITO) or an indium zinc oxide (IZO).

The first color filter 181 may be disposed on the first planarization layer 140 and may be disposed in the emitting area EA. That is, the first color filter 181 may be disposed below the light emitting device 160. The first color filter 181 may transmit light in a particular color wavelength band, such as a red wavelength band. Accordingly, when the light generated by the light emitting device 160 is incident on the first color filter 181, red light may be emitted from the first color filter 181. That is, the first sub-pixel SP1 may emit red light, but is not limited thereto.

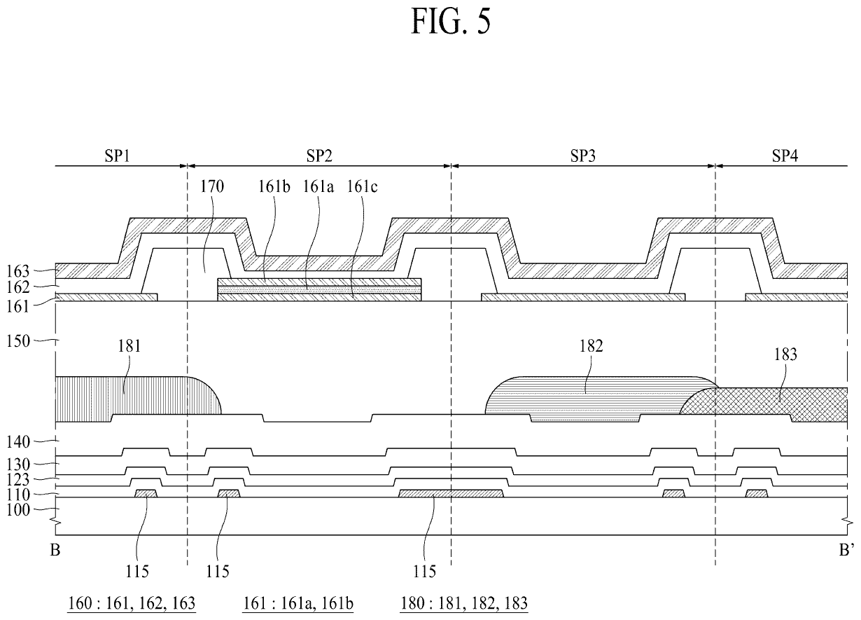

FIG. 4 is a cross-sectional view of a pixel P according to a first embodiment of the present disclosure. In detail, FIG. 4 is a cross-sectional view of the first to fourth sub-pixels SP1 to SP4 taken along line B-B′ of FIG. 2.

As described in FIG. 4, each of the sub-pixels SP may include a substrate 100, a buffer layer 110, a light blocking layer 115, a thin film transistor 120, a passivation layer 130, a first planarization layer 140, a second planarization layer 150, a light emitting device 160, and a bank 170, and the like. FIG. 4 is a cross-sectional view taken along line B-B′ of FIG. 2, and thus a structure of the thin film transistor 120 is not shown.

Referring to FIG. 4, the buffer layer 110, the light blocking layer 115, a gate insulating layer 123 of the thin film transistor 120, a passivation layer 130, a first planarization layer 140, and a second planarization layer 150 may be sequentially disposed on the substrate 100, but is not limited thereto.

The light blocking layer 115 may be disposed at a position overlapping the bank 170. Also, the light blocking layer 115 may be patterned. For example, the plurality of light blocking layers 115 spaced apart from each other may be disposed between the first and second sub-pixels SP1 and SP2, but are not limited thereto. Also, one light blocking layer 115 may be disposed between the second and third sub-pixels SP2 and SP3, but is not limited thereto. Also, the plurality of light blocking layers 115 spaced apart from each other may be disposed between the third and fourth sub-pixels SP3 and SP4, without being limited thereto.

A plurality of color filters such as a first color filter, a second color filter and a third color filter 181, 182 and 183 may be disposed on the first planarization layer 140. The first color filter 181 may be disposed in the first sub-pixel SP1 and may transmit a light of a first color such as red light, without being limited thereto. The second color filter 182 may be disposed in the third sub-pixel SP3 and may transmit a light of a second color such as blue light, without being limited thereto. The third color filter 183 may be disposed in the fourth sub-pixel SP4 and may transmit a light of a third color such as green light, without being limited thereto. Also, since the second sub-pixel SP2 emits white light, the second sub-pixel SP2 may not include a color filter.

Each of the first to fourth sub-pixels SP1 to SP4 may include the light emitting device 160. As described above, the light emitting device 160 may include a first electrode 161, a light emitting layer 162, and a second electrode 163, without being limited thereto.

The first electrode 161 of the first sub-pixel SP1 may include a transparent conductive material such as an indium tin oxide (ITO) or an indium zinc oxide (IZO), without being limited thereto. Likewise, the first electrodes 161 of the third and fourth sub-pixels SP3 and SP4 may include the transparent conductive material such as an indium tin oxide (ITO) or an indium zinc oxide (IZO), without being limited thereto. Also, the first electrodes 161 of the first to fourth sub-pixels SP1 to SP4 may be separated by the bank 170.

Meanwhile, the first electrode 161 of the second sub-pixel SP2 emitting white light may include a first conductive layer 161a and a second conductive layer 161b, without being limited thereto.

The first conductive layer 161a may be disposed on the second planarization layer 150. The first conductive layer 161a may be disposed on an entire area of the emitting area EA of the second sub-pixel SP2. Also, the first conductive layer 161a may be formed of a conductive material having high transmittance, without being limited thereto. For example, the first conductive layer 161a may be formed of a metal oxide. Also, the first conductive layer 161a may be formed of a transparent conductive material such as an indium tin oxide (ITO) or an indium zinc oxide (IZO), without being limited thereto. Also, the first conductive layer 161a may be a metal thin film having a thickness of 500 Å or less.

The second conductive layer 161b may be disposed on the first conductive layer 161a. Also, the second conductive layer 161b may be disposed on the entire area of the emitting area EA of the second sub-pixel SP2, and may cover an entire upper surface US of the first conductive layer 161a. The second conductive layer 161b may be made of a transparent conductive material such as an indium tin oxide (ITO) or an indium zinc oxide (IZO). That is, a transmittance of the second conductive layer 161b may be greater than or equal to that of the first conductive layer 161a, without being limited thereto.

The light emitting layer 162 of the first to fourth sub-pixels SP1 to SP4 may be formed of the same material, but is not limited thereto. All of the light emitting layers 162 of the first to fourth sub-pixels SP1 to SP4 may generate white light. Alternatively, the light emitting layer 162 of the first sub-pixel SP1 may generate red light, the light emitting layer 162 of the second sub-pixel SP2 may emit white light, the light emitting layer 162 of the third sub-pixel SP3 may emit blue light, and the light emitting layer 162 of the fourth sub-pixel SP4 may emit green light, but is not limited thereto. Also, the light emitting layer 162 of the first to fourth sub-pixels SP1 to SP4 may be continuously formed on the bank 170, but is not limited thereto.

Likewise, the second electrodes 163 of the first to fourth sub-pixels SP1 to SP4 may be formed of the same material, but is not limited thereto. That is, the second electrodes 163 of the first to fourth sub-pixels SP1 to SP4 may be formed of a highly reflective metal material. Also, the second electrodes 163 of the first to fourth sub-pixels SP1 to SP4 may be continuously formed on the bank 170, but the present disclosure is not limited thereto. Specifically, the second electrodes 163 of the first to fourth sub-pixels SP1 to SP4 may be continuously formed on the light emitting layer 162, but the present disclosure is not limited thereto.

That is, the first exemplary embodiment of the present disclosure discloses that the first electrode 161 of the second sub-pixel SP2 emitting white light has a double layer structure in a bottom emission type, but the present disclosure is not limited thereto. Specifically, the first electrode 161 may include the first conductive layer 161a made of a conductive material having high transmittance and the second conductive layer 161b made of a transparent conductive material, but the present disclosure is not limited thereto.

The first exemplary embodiment of the present disclosure is the bottom emission type, and in order to improve the light efficiency of the display device, the second electrode 163 of the light emitting device 160 may be formed of a highly reflective metal material., but the present disclosure is not limited thereto. Specifically, when the light generated by the light emitting layer 162 of the light emitting device proceeds toward the upper portion of the display device, the light may be reflected by the second electrode 163. Accordingly, the path of the light may be changed from a direction of the upper portion of the display device to a direction of the lower portion of the display device. Accordingly, the light directed toward the lower portion of the display device may increase, and thus the light efficiency of the display device may be improved.

In this case, external light may penetrate from the lower portion of the substrate 100 into the display device. When external light penetrates into the first sub-pixel, the third sub-pixel and the fourth sub-pixel SP1, SP3 and SP4, external light may be absorbed through the first to third color filters 181 to 183. Specifically, when external light penetrates into red, green, and blue sub-pixels, external light may be absorbed through the color filter. However, since the second sub-pixel SP2 such as white sub-pixel does not include the color filter, external light may be reflected by the second electrode 163. Accordingly, the reflectance of the display device with respect to external light may increase.

However, the first exemplary embodiment of the present disclosure has the effect of reducing or minimizing the reflectance of the display device with respect to external light by forming the first electrode 161 of the second sub-pixel SP2 emitting white light in a double layer structure.

In detail, after passing through the first electrode 161 in the second sub-pixel SP2, an external light L1 may be reflected by the second electrode 163. Then, the external light L1 may pass through the first electrode 161 again. In this process, destructive interference occurs due to the first conductive layer 161a having high transmittance, and an amount of the light L1′ finally passing through the first electrode 161 may decrease compared to an amount of the first incident light L1. Thus, the reflectance of the display device with respect to the external light may be reduced.

Also, in order for the sub-pixel SP to emit light, a light L2 generated in the light emitting layer 162 may pass through the first conductive layer 161a toward the lower portion of the substrate 100. In this case, since the first conductive layer 161a has a high transmittance, an amount of light L2 generated in the light emitting layer 162 may be maintained to some extent even if the light L2 passes through the first conductive layer 161a. Accordingly, it is possible to minimize the reduction of the light generated in the light emitting layer 162 by the first conductive layer 161a.

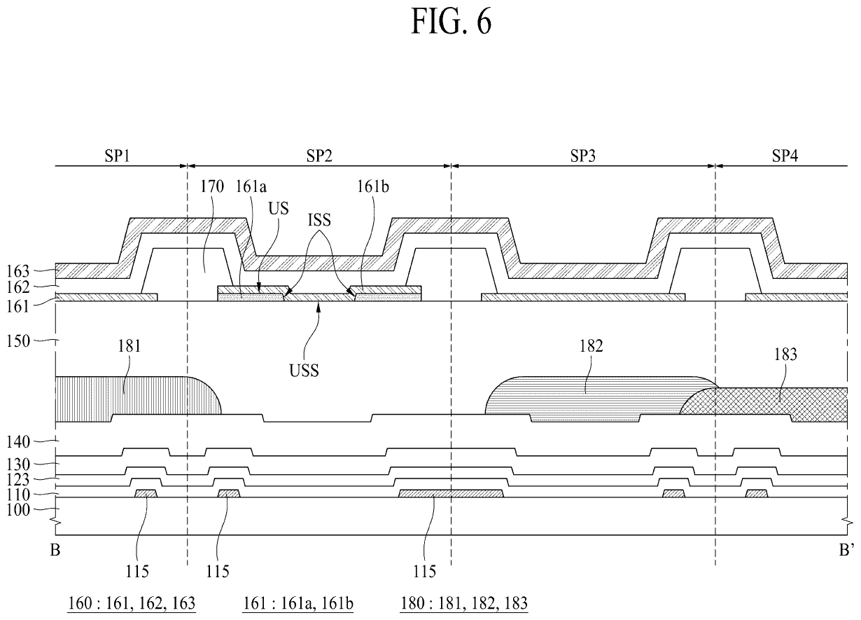

FIG. 5 is a cross-sectional view of a pixel P according to a second exemplary embodiment of the present disclosure.

Compared with FIG. 4, FIG. 5 illustrates substantially the same structure except for the structure of the first electrode 161 of the second sub-pixel SP2. Accordingly, the same reference numerals are used for components or substantially the same that are the same as those of the pixel P illustrated in FIG. 4, and repeated descriptions are omitted or briefly provided.

Referring to FIG. 5, the first electrode 161 of the second sub-pixel SP2 may further include a third conductive layer 161c in addition to the first conductive layer and second conductive layer 161a and 161b. The third conductive layer 161c may be disposed between the first conductive layer 161a and the second planarization layer 150. Specifically, the third conductive layer 161c may be disposed on the second planarization layer 150 and may be disposed on the entire area of the emitting area EA of the second sub-pixel SP2. The first conductive layer 161a may be disposed on the third conductive layer 161c and may be disposed on the entire area of the emitting area EA of the second sub-pixel SP2. The second conductive layer 161b may be disposed on the first conductive layer 161a and may be disposed on the entire area of the emitting area EA of the second sub-pixel SP2. Also, the third conductive layer 161c may be made of a transparent conductive material, such as an indium tin oxide (ITO) or an indium zinc oxide (IZO). Accordingly, while an adhesion between the first electrode 161 and the second planarization layer 150 is increased, an influence of the destructive interference may be increased when external light is penetrated.

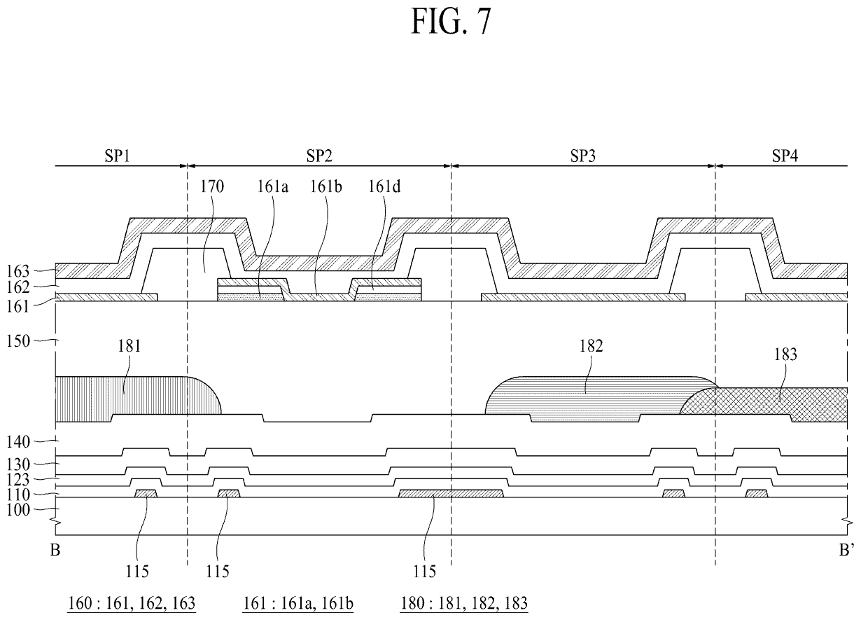

FIG. 6 is a cross-sectional view of a pixel P according to a third exemplary embodiment of the present disclosure.

Compared with FIG. 4, FIG. 6 illustrates substantially the same structure except for the structure of the first electrode 161 of the second sub-pixel SP2. Accordingly, the same reference numerals are used for components that are the same or substantially the same as those of the pixel P illustrated in FIG. 4, and repeated descriptions are omitted or briefly provided.

Referring to FIG. 6, the first electrode 161 of the second sub-pixel SP2 may include a first conductive layer and a second conductive layer 161a and 161b. In this case, the first conductive layer 161a may not be disposed on the entire area of the emitting area EA of the second sub-pixel SP2. The first conductive layer 161a may be formed in a ring shape surrounding an edge of the emitting area EA of the second sub-pixel SP2. That is, the first conductive layer 161a may not be disposed in a center of the emitting area EA of the second sub-pixel SP2.

As one example, the second conductive layer 161b may be disposed on the first conductive layer 161a and may be disposed on the entire area of the emitting area EA of the second sub-pixel SP2, but is not limited thereto. That is, the second conductive layer 161b may cover an upper surface US and an inner side surface ISS of the first conductive layer 161a. Also, the second conductive layer 161b may cover an upper surface USS of the second planarization layer 150 exposed by the first conductive layer 161a.

Accordingly, the third exemplary embodiment of the present disclosure discloses that only a partial area of the first electrode 161 of the second sub-pixel SP2 is formed as a double layer. That is, an edge area of the first electrode 161 may include first and second conductive layers 161a and 161b, and a central area of the first electrode 161 may include only the second conductive layer 161b. Accordingly, the light generated by the light emitting layer 162 may not pass through the first conductive layer 161a, but may pass through the second conductive layer 161b only. Accordingly, compared with the first embodiment, a possibility that an amount of light generated by the light emitting layer 162 is reduced is further reduced, thereby further preventing the light efficiency of the display device from being reduced.

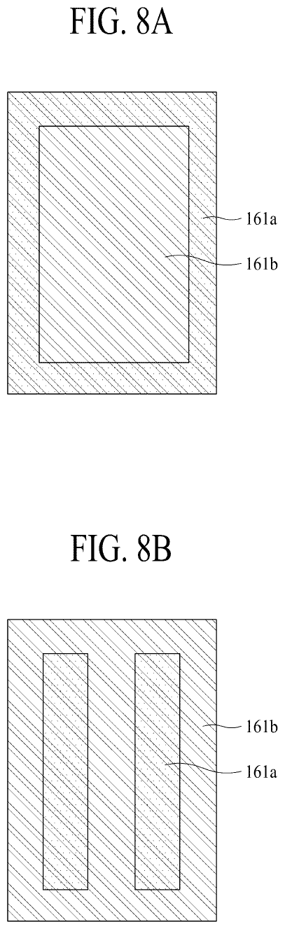

FIG. 7 is a cross-sectional view of a pixel P according to a fourth exemplary embodiment of the present disclosure.

Compared with FIG. 6, FIG. 7 illustrates substantially the same structure except for the structure of the first electrode 161 of the second sub-pixel SP2. Accordingly, the same reference numerals are used for components that are the same or substantially the same as those of the pixel P illustrated in FIG. 6, and repeated descriptions are omitted or briefly provided.

Referring to FIG. 7, the first electrode 161 of the second sub-pixel SP2 may further include a fourth conductive layer 161d in addition to the first conductive layer and second conductive layer 161a and 161b.

The fourth conductive layer 161d may be disposed between the first and second conductive layers 161a and 161b. Also, the fourth conductive layer 161d may have a shape corresponding to that of the first conductive layer 161a, but is not limited thereto. That is, as described above in FIG. 6, since the first conductive layer 161a is formed in a ring shape surrounding the edge of the emitting area EA of the second sub-pixel SP2, the fourth conductive layer 161d may also be formed in a ring shape surrounding the edge of the emitting area EA of the second sub-pixel SP2, but is not limited thereto.

The fourth conductive layer 161d may be formed of a highly reflective metal material. The fourth conductive layer 161d may include a metal material such as aluminum (Al), silver (Ag), copper (Cu), molybdenum (Mo), titanium (Ti), tungsten (W), or chromium (Cr), or an alloy thereof, but is not limited thereto.

Accordingly, when external light is penetrated, the light may be reflected by the fourth conductive layer 161d. The light reflected by the fourth conductive layer 161d may be directed to the first and third sub-pixels SP1 and SP3 adjacent to the second sub-pixel SP2. Since the first color filter 181 is disposed in the first sub-pixels SP1 and the second color filter 182 is disposed in the third sub-pixels SP3, the light reflected by the fourth conductive layer 161d may be directed to the first and second color filters 181 and 182. Accordingly, the external light may be absorbed by the first and second color filters 181 and 182. Therefore, the external light may be further reduced. Also, since the fourth conductive layer 161d is disposed in the edge of the emitting area EA of the second sub-pixel SP2, an influence on the path of light generated by the light emitting layer 162 may be reduced or minimized.

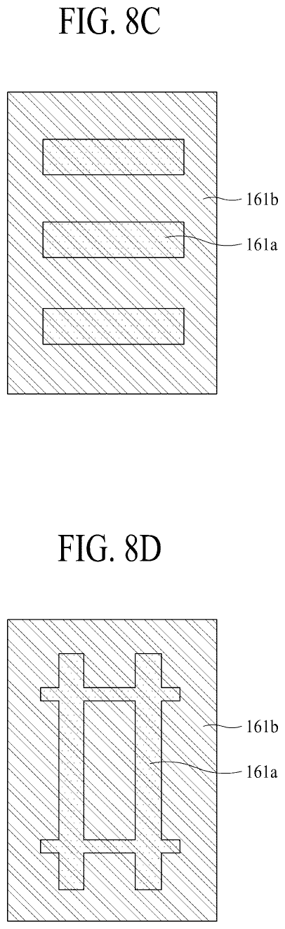

FIGS. 8A to 8D are plan views of a sub-pixel according to various exemplary embodiments. Specifically, FIGS. 8A to 8D are plan views of the first electrode 161 of the second sub-pixel SP2.

FIG. 8A is a plan view of the third embodiment described above in FIG. 6. That is, the first conductive layer 161a may be formed in a ring shape surrounding the edge of the emitting area EA and may not be disposed on the entire area of the emitting area EA of the second sub-pixel SP2. Also, the second conductive layer 161b may be disposed on the first conductive layer 161a and may be disposed on the entire area of the emitting area EA of the second sub-pixel SP2. That is, the second conductive layer 161b may cover the upper surface and the inner side surface of the first conductive layer 161a and the upper surface of the second planarization layer 150 exposed by the first conductive layer 161a.

Also, the first conductive layer 161a may include not a single layer but a plurality of regions spaced apart from each other. Referring to FIG. 8B, the first conductive layer 161a may include a plurality of regions spaced apart from each other in a first direction. Alternatively, referring to FIG. 8C, the first conductive layer 161a may include a plurality of regions spaced apart from a second direction crossing the first direction. The first conductive layer 161a may be spaced apart from the edge of the emitting area EA. Also, the second conductive layer 161b may be disposed on the first conductive layer 161a and may be disposed on the entire area of the emitting area EA of the second sub-pixel SP2. That is, the second conductive layer 161b may cover the upper surface of the first conductive layer 161a.

Referring to FIG. 8D, the first conductive layer 161a may be formed along the first and second directions and may have a shape crossing each other. For example, the first conductive layer 161a may have a shape in which two regions spaced apart from each other in the first direction and two regions spaced apart from each other in the second direction overlap. Also, the first electrode 161 of the second sub-pixel SP2 is not limited to the shape disclosed in FIGS. 8A to 8D, and may have various shapes.

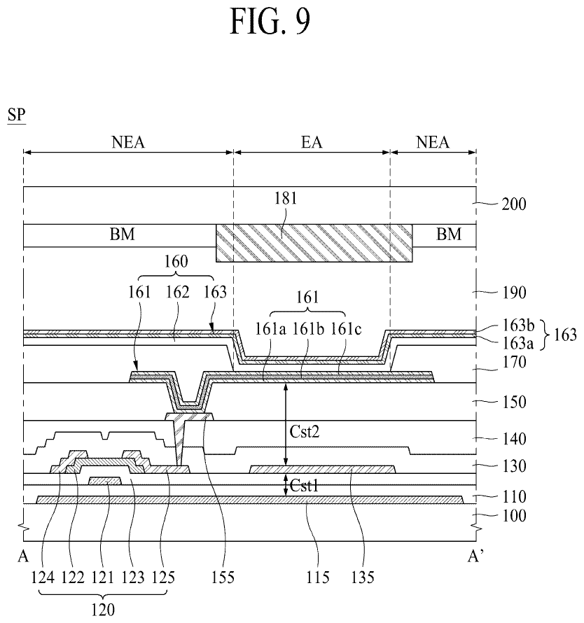

FIG. 9 is a cross-sectional view of one sub-pixel SP according to another exemplary embodiment of the present disclosure. In detail, FIG. 9 is a cross-sectional view of the first sub-pixel SP1 taken along line A-A′ of FIG. 2.

Since FIG. 9 discloses substantially the same structure as FIG. 4, the same reference numerals are used for the components that are the same or substantially the same as those of the sub-pixel SP shown in FIG. 3, and repeated descriptions are omitted or briefly provided.

The exemplary embodiment of FIG. 3 discloses the bottom emission type in which the emitted light is emitted downward, whereas the embodiment of FIG. 9 discloses a top emission type in which the emitted light is emitted upward. Therefore, a transparent material or an opaque material may be used as a material of a lower substrate 100.

The light blocking layer 115 may be disposed on the lower substrate 100. The light blocking layer 115 may be disposed in an area overlapping the thin film transistor 120. Also, it may be disposed in both the emitting area EA and the non-emitting area NEA.

The thin film transistor 120 may be disposed on the buffer layer 110. The thin film transistor 120 may include a gate electrode 121, a semiconductor layer 122, a gate insulation layer 123, a first electrode such as a source electrode 124, a second electrode such as a drain electrode 125, and the like, but the present disclosure is not limited thereto. Although a bottom gate structure in which a semiconductor layer 122 is disposed on a gate electrode 121 is disclosed in FIG. 9, it is not limited thereto. For example, a top gate structure in which the gate electrode 121 is disposed on the semiconductor layer 122 may be disclosed.

A auxiliary electrode 135 may be disposed on the gate insulating layer 123. The auxiliary electrode 135 may be formed of the same material through the same process as the semiconductor layer 112, but is not limited thereto. The passivation layer 130 may be disposed on the semiconductor layer 112 and the auxiliary electrode 135.

The first and second planarization layers 140 and 150 may be disposed on the thin film transistor 120. The first planarization layer 140 may be disposed on the thin film transistor 120, and the second planarization layer 150 may be disposed on the first planarization layer 140. The first and second planarization layers 140 and 150 may protect the thin film transistor 120.

The light emitting device 160 may be disposed on the second planarization layer 150. The light emitting device 160 may include a first electrode 161, a light emitting layer 162, and a second electrode 163, but is not limited thereto.

The first electrode 161 may be disposed on the second planarization layer 150 and may function as an anode of the display device. The first electrode 161 may be electrically connected with the drain electrode 125 of the thin film transistor 120 through a connection electrode 155 disposed on the first planarization layer 140.

The first electrode 161 may include a first transparent conductive layer 161a, a reflective layer 161b, and a second transparent conductive layer 161c, without being limited thereto.

The first transparent conductive layer 161a may be disposed on the second planarization layer 150. The first transparent conductive layer 161a may include a transparent conductive material such as an indium tin oxide (ITO) or an indium zinc oxide (IZO), without being limited thereto.

The reflective layer 161b may be disposed on the first transparent conductive layer 161a. The reflective layer 161b may be formed of a metal material. For example, the reflective layer 161b may include a metal material such as aluminum (Al), silver (Ag), copper (Cu), molybdenum (Mo), titanium (Ti), tungsten (W), or chromium (Cr), or an alloy thereof, without being limited thereto.

The second transparent conductive layer 161c may be disposed on the reflective layer 161b. The second transparent conductive layer 161c may include a transparent conductive material such as an indium tin oxide (ITO) or an indium zinc oxide (IZO), without being limited thereto.

The light emitting layer 162 may be disposed on the first electrode 161. The light emitting layer 162 may also be disposed on an upper surface of the bank 170. The light emitting layer 162 may be disposed on the entire area of the emitting area EA and the non-emitting area NEA.

The second electrode 163 may be disposed on the light emitting layer 162. The second electrode 163 may include a first conductive layer 163a and a second conductive layer 163b, and the like.

The first conductive layer 163a may be disposed on the light emitting layer 162. The first conductive layer 163a may be disposed on the entire area of the emitting area EA and the non-emitting area NEA. Also, the first conductive layer 163a may be formed of a material having high transmittance, without being limited thereto. For example, the first conductive layer 163a may be formed of a metal oxide, without being limited thereto. Also, the first conductive layer 163a may be formed of a transparent conductive material such as an indium tin oxide (ITO) or an indium zinc oxide (IZO), without being limited thereto. Also, the first conductive layer 163a may be a metal thin film having a thickness of 500 Å or less. For example, the first conductive layer 163a may be a thin film including a metal such as aluminum (Al), silver (Ag), copper (Cu), molybdenum (Mo), titanium (Ti), tungsten (W), or chromium (Cr), without being limited thereto.

The second conductive layer 163b may be disposed on the first conductive layer 163a. Also, the second conductive layer 163b may be disposed on the entire emitting area EA and the non-emitting area NEA, and may cover an entire upper surface of the first conductive layer 163a. The second conductive layer 163b may be formed of a transparent conductive material such as an indium tin oxide (ITO) or an indium zinc oxide (IZO), without being limited thereto. That is, a transmittance of the second conductive layer 163b may be greater than or equal to that of the first conductive layer 163a, without being limited thereto.

The first color filter 181 and the black matrix BM may be disposed on a lower surface of an upper substrate 200. The first color filter 181 may be disposed in the emitting area EA, and the black matrix BM may be disposed in the non-emitting area NEA. The black matrix BM may absorb light.

The lower substrate 100 and the upper substrate 200 may be bonded by an encapsulation layer 190. That is, the encapsulation layer 190 may be disposed between the light emitting device 160 and the color filter 181. The encapsulation layer 190 may include an organic insulating material such as an acrylic resin, an epoxy resin, a phenolic resin, a polyamide resin, a polyimide resin, or the like but is not limited thereto. Also, the encapsulation layer 190 may include an inorganic insulating material such as silicon nitride (SIN), silicon oxide (SiO), silicon oxynitride (SiON) and aluminum oxide (AlO).

Referring to FIG. 9, a structure in which an insulating layer is disposed between the light blocking layer 115 and the auxiliary electrode 135 may be disclosed. Accordingly, a first storage capacitor Cst1 may be formed. Also, a structure in which an insulating layer is disposed between the auxiliary electrode 135 and the first electrode 161 may be disclosed. Accordingly, a second storage capacitor Cst2 may be formed.

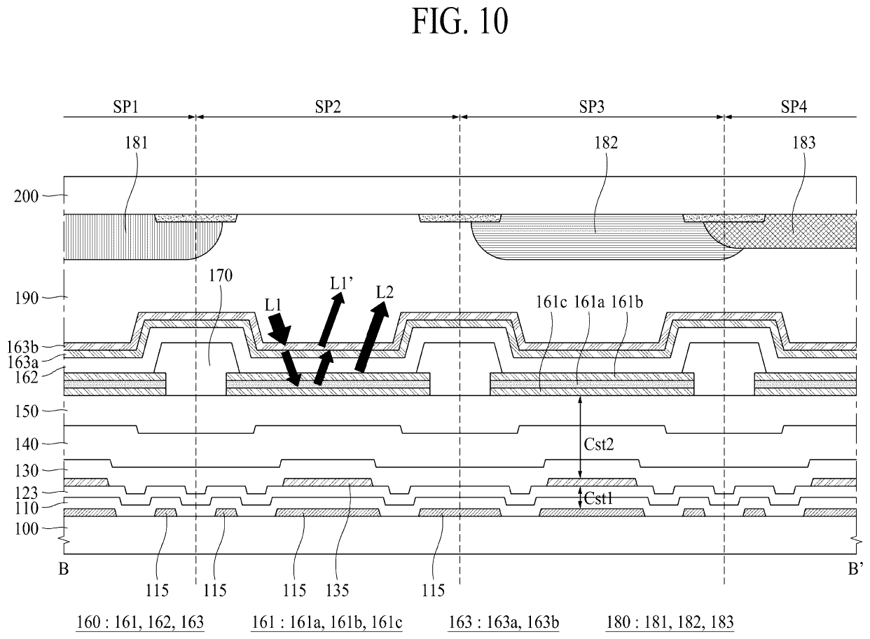

FIG. 10 is a cross-sectional view of a pixel according to a fifth exemplary embodiment of the present disclosure. In detail, FIG. 10 is a cross-sectional view of the first to fourth sub-pixels SP1 to SP4 taken along line B-B′ of FIG. 2.

As described above in FIG. 9, each of the sub-pixels SP may include a lower substrate 100, a buffer layer 110, a light blocking layer 115, a thin film transistor 120, a passivation layer 130, a first planarization layer 140, a second planarization layer 150, a light emitting device 160, a bank 170, and the like.

Referring to FIG. 10, the buffer layer 110, the light blocking layer 115, a gate insulating layer 123 of the thin film transistor 120, an auxiliary electrode 135, the passivation layer 130, the first planarization layer 140, and the second planarization layer 150 may be sequentially disposed on the lower substrate 100, but is not limited thereto.

The light blocking layer 115 may be disposed at a position overlapping the bank 170. Also, the light blocking layer 115 may be disposed at a position overlapping the light emitting device 160.

A plurality of color filters such as first to third color filters 181 to 183 may be disposed on a lower surface of an upper substrate 200. The first color filter 181 may be disposed in the first sub-pixel SP1 and may transmit a light of a first color such as red light, without being limited thereto. The second color filter 182 may be disposed in the third sub-pixel SP3 and may transmit a light of a second color such as blue light, without being limited thereto. The third color filter 183 may be disposed in the fourth sub-pixel SP4 and may transmit a light of a third color such as green light, without being limited thereto. Also, since the second sub-pixel SP2 emits white light, the second sub-pixel SP2 may not include a color filter.

The black matrix BM may be disposed on the lower surface of the upper substrate 200. Also, the black matrix BM may be disposed in a boundary area of the sub-pixels SP adjacent to each other.

Each of the first to fourth sub-pixels SP1 to SP4 may include a light emitting device 160. As described above, the light emitting device 160 may include a first electrode 161, a light emitting layer 162, and a second electrode 163, but is not limited thereto.

The first electrode 161 of the first sub-pixel SP1 may include a first transparent conductive layer 161a, a reflective layer 161b, and a second transparent conductive layer 163c, but is not limited thereto. Likewise, the first electrode 161 of each of the second to fourth sub-pixels SP2 to SP4 may include the first transparent conductive layer 161a, the reflective layer 161b, and the second transparent conductive layer 163c. The first electrode 161 of each of the first to fourth sub-pixels SP1 to SP4 may be separated by the bank 170.

The light emitting layer 162 of the first to fourth sub-pixels SP1 to SP4 may be formed of the same material, but is not limited thereto. All of the light emitting layers 162 of the first to fourth sub-pixels SP1 to SP4 may generate white light. Alternatively, the light emitting layer 162 of the first sub-pixel SP1 may generate red light, the light emitting layer 162 of the second sub-pixel SP2 may emit white light, the light emitting layer 162 of the third sub-pixel SP3 may emit blue light, and the light emitting layer 162 of the fourth sub-pixel SP4 may emit green light, but is not limited thereto. Also, the light emitting layer 162 of the first to fourth sub-pixels SP1 to SP4 may be continuously formed on the bank 170, but is not limited thereto.

The second electrode 163 of the first sub-pixel SP1 may include a first conductive layer 163a and a second conductive layer 163b. Likewise, the second electrode 163 of each of the second to fourth sub-pixels SP2 to SP4 may include the first conductive layer 163a and the second conductive layer 163b. The second electrodes 163 of the first to fourth sub-pixels SP1 to SP4 may be continuously formed on the bank 170, but the present disclosure is not limited thereto.

That is, the fifth exemplary embodiment of the present disclosure discloses that the second electrodes 163 of the first to fourth sub-pixels SP1 to SP4 have a double layer structure in the top emission type, but is not limited thereto. Specifically, the second electrode 163 may include the first conductive layer 162a made of a conductive material having high transmittance and the second conductive layer 162b made of a transparent conductive material.

The fifth exemplary embodiment of the present disclosure is the top emission type, and in order to improve the light efficiency of the display device, the first electrode 161 of the light emitting device 160 is formed to include the reflective layer 161b. Specifically, when the light generated by the light emitting layer 162 of the light emitting device proceeds toward a lower portion of the display device, the light is reflected by the reflective layer 161b of the first electrode 161. Accordingly, a path of the light may be changed from a direction of the lower portion of the display device to a direction of an upper portion of the display device. Therefore, light directed toward the upper portion of the display device may increase, and thus the light efficiency of the display device may be improved.

In this case, external light may be penetrated from an upper portion of the upper substrate 200 to the inside of the display device. When external light is penetrated into the first sub-pixel, the third sub-pixel and the fourth sub-pixel SP1, SP3 and SP4, external light may be absorbed through the first to third color filters 181 to 183. Specifically, when the external light is penetrated into the red, green, and blue sub-pixels, the external light may be absorbed through the color filter. However, since the second sub-pixel SP2 such as white sub-pixel does not include a color filter, the external light may be reflected by the reflective layer 161b of the first electrode 161. Accordingly, the reflectance of the display device with respect to the external light may increase.

However, the fifth exemplary embodiment of the present disclosure has the effect of reducing or minimizing the reflectance of the display device to external light by forming the second electrode 163 of the first to fourth sub-pixels SP1 to SP4 in a double layer structure.

In detail, after passing through the second electrode 163 in the second sub-pixel SP2, an external light L1 may be reflected by the reflective layer 161b of the first electrode 161. Then, the external light L1 may pass through the second electrode 163 again. In this process, destructive interference occurs due to the first conductive layer 163a having high transmittance, and an amount of light L1′ finally passing through the second electrode 163 may decrease compared to an amount of the first incident light L1. Thus, the reflectance of the display device with respect to the external light may be reduced.

Also, in order for the sub-pixel SP to emit light, a light L2 generated in the light emitting layer 162 may pass through the first conductive layer 163a toward the upper substrate 200. In this case, since the first conductive layer 163a has a high transmittance, an amount of light L2 generated in the light emitting layer 162 may be maintained to some extent even if the light L2 passes through the first conductive layer 163a. Accordingly, it is possible to minimize the reduction of the light generated in the light emitting layer 162 by the first conductive layer 163a.

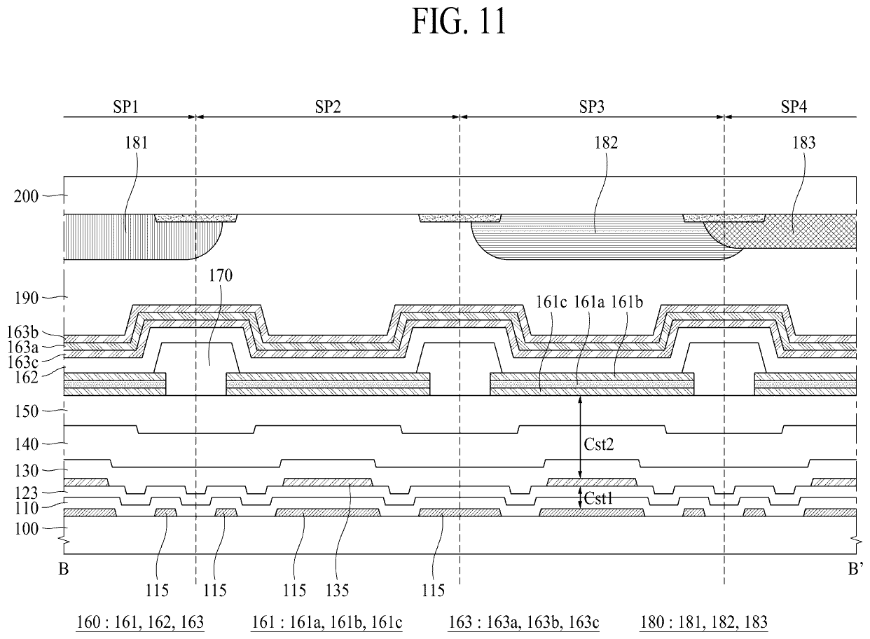

FIG. 11 is a cross-sectional view of a pixel P according to a sixth exemplary embodiment of the present disclosure.

Compared with FIG. 10, FIG. 11 discloses substantially the same structure except for the structures of the second electrodes 163 of the first to fourth sub-pixels SP1 to SP4. Accordingly, the same reference numerals are used for components that are the same or substantially the same as those of the pixel P shown in FIG. 10, and repeated descriptions are omitted.

Referring to FIG. 11, the second electrodes 163 of the first to fourth sub-pixels SP1 to SP4 may further include a third conductive layer 163c in addition to the first conductive layer 163a and the second conductive layer 163b. The third conductive layer 163c may be disposed between the first conductive layer 163a and the light emitting layer 162. The third conductive layer 163c may be disposed on the entire area of the emitting area EA and the non-emitting area NEA. Also, the third conductive layer 163c may be formed of a material having high transmittance. For example, the third conductive layer 163c may be formed of a metal oxide. Also, the third conductive layer 163c may be formed of a transparent conductive material such as an indium tin oxide (ITO) or an indium zinc oxide (IZO), without being limited thereto. Also, the third conductive layer 163c may be a metal thin film having a thickness of 500 Å or less. Accordingly, when external light is penetrated, the influence of the destructive interference may be increased.

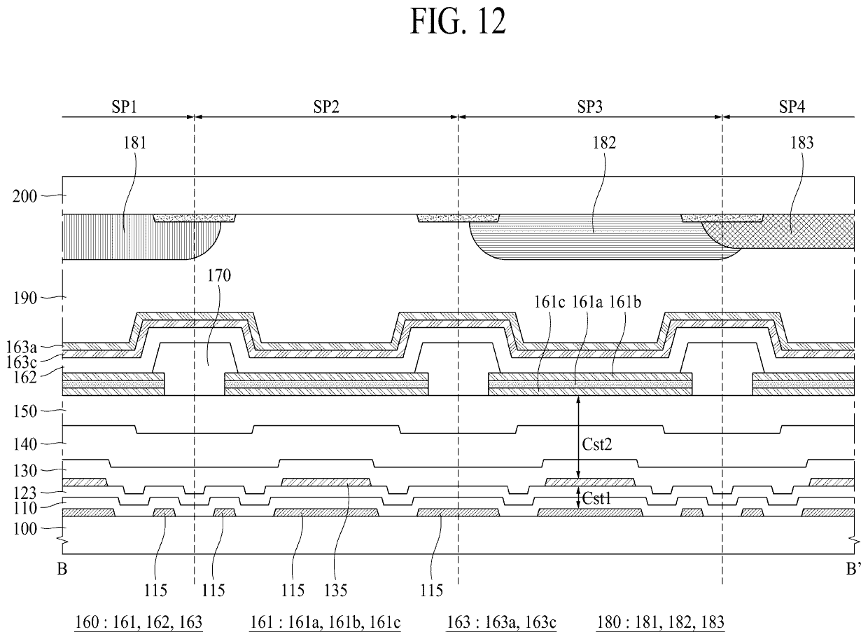

FIG. 12 is a cross-sectional view of a pixel according to a seventh exemplary embodiment of the present disclosure.

FIG. 12 discloses a structure in which the second conductive layer 163b is omitted in the sixth embodiment of FIG. 11. That is, the second electrodes 163 of the first to fourth sub-pixels SP1 to SP4 may include the first and third conductive layers 163a and 163c. The third conductive layer 163c may be disposed between the first conductive layer 163a and the light emitting layer 162. Also, the first conductive layer 163a may be in contact with the encapsulation layer 190. Accordingly, while the adhesion between the second electrode 163 and the encapsulation layer 190 is increased, the destructive interference function may be performed when external light is penetrated.

According to the present disclosure, the following advantageous effects may be obtained.

According to the present disclosure, the plurality of light conversion layers may be formed so that light efficiency may be improved, and reflectance due to external light may be reduced.

A display device according to one or more exemplary embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc, but embodiments of the present disclosure are not limited thereto.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate on which a first sub-pixel and a second sub-pixel are disposed, each of the first sub-pixel and the second sub-pixel including an emitting area and a non-emitting area adjacent to the emitting area,
wherein each of the first and second sub-pixels includes:
a first electrode disposed in the emitting area;
a light emitting layer disposed on the first electrode; and
a second electrode disposed on the light emitting layer,
wherein, in operation, the first sub-pixel emits a light of a first color different from a light emitted by the second sub-pixel, and the second sub-pixel emits white light, and
wherein a structure of the first electrode of the first sub-pixel and a structure of the first electrode of the second sub-pixel are different from each other.

2. The display device of claim 1, wherein the light of the first color comprises any one of red, green, and blue light.

3. The display device of claim 2, wherein the first electrode of the first sub-pixel includes a transparent conductive layer,
wherein the first electrode of the second sub-pixel includes a first conductive layer and a second conductive layer disposed on the first conductive layer, and
wherein a transmittance of the second conductive layer is greater than or equal to a transmittance of the first conductive layer.

4. The display device of claim 3, wherein the first conductive layer includes metal oxide, and the second conductive layer includes a transparent conductive material.

5. The display device of claim 3, wherein the first electrode of the second sub-pixel further includes a third conductive layer disposed on a lower surface of the first conductive layer, and the third conductive layer includes a transparent conductive material.

6. The display device of claim 4, wherein the first conductive layer is disposed on an entire surface of the emitting area of the second sub-pixel, and
the second conductive layer is disposed on the entire surface of the emitting area of the second sub-pixel and covers an upper surface of the first conductive layer.

7. The display device of claim 3, wherein the first conductive layer has a ring shape surrounding an edge of the emitting area of the second sub-pixel, and
wherein the second conductive layer is disposed on an entire surface of the emitting area of the second sub-pixel and covers an upper surface and an inner side surface of the first conductive layer.

8. The display device of claim 7, wherein the second conductive layer covers the upper surface and the inner side surface of the first conductive layer and an upper surface of a planarization layer exposed by the first conductive layer.

9. The display device of claim 7, wherein the first electrode of the second sub-pixel further includes a fourth conductive layer disposed between the first and second conductive layers, and the fourth conductive layer has a shape corresponding to a shape of the first conductive layer.

10. The display device of claim 9, wherein the fourth conductive layer has a higher reflectance than the first and second conductive layers.

11. The display device of claim 3, wherein the first conductive layer includes a plurality of regions spaced apart from each other in the emitting area of the second sub-pixel, and
wherein the second conductive layer is disposed on an entire area of the light emitting area of the second sub-pixel and covers an upper surface of the plurality of regions of the first conductive layer.

12. The display device of claim 1, wherein the first sub-pixel includes any one of a red color filter, a green color filter, and a blue color filter disposed below the first electrode.

13. The display device of claim 1, further comprising a third sub-pixel disposed on the substrate and emitting light different from a light emitted by the first sub-pixel,
wherein the third sub-pixel emits any one of red, green, and blue light,
wherein a structure of a first electrode of the third sub-pixel and a structure of the first electrode of the first sub-pixel are the same as each other, and
wherein a structure of the first electrode of the third sub-pixel and a structure of the first electrode of the second sub-pixel are different from each other.

14. The display device of claim 13, further comprising a fourth sub-pixel disposed on the substrate and emitting light different from a light emitted by the first sub-pixel and the third sub-pixel,
wherein the fourth sub-pixel emits any one of red, green, and blue light,
a structure of a first electrode of the fourth sub-pixel and a structure of the first electrode of the first sub-pixel are the same, and
a structure of the first electrode of the fourth sub-pixel and a structure of the first electrode of the second sub-pixel are different.

15. A display device comprising:
a substrate on which a plurality of sub-pixels is disposed, the plurality of sub-pixels including an emitting area and a non-emitting area adjacent to the emitting area,
wherein each of the plurality of sub-pixels includes:
a first electrode disposed in the emitting area;
a light emitting layer disposed on the first electrode; and
a second electrode disposed on the light emitting layer,
wherein the second electrode includes a first conductive layer and a second conductive layer disposed on the first conductive layer, and
wherein a transmittance of the second conductive layer is different from a transmittance of the first conductive layer.

16. The display device of claim 15, wherein the transmittance of the second conductive layer is greater than or equal to the transmittance of the first conductive layer.

17. The display device of claim 16, wherein the first conductive layer includes metal oxide, and the second conductive layer includes a transparent conductive material.

18. The display device of claim 17, wherein the second electrode further includes a third conductive layer disposed below the first conductive layer, and the third conductive layer includes a metal oxide.

19. The display device of claim 18, wherein the second electrode includes the first conductive layer and the third conductive layer disposed below the first conductive layer without the second conductive layer.

20. The display device of claim 15, wherein the transmittance of the first conductive layer is greater than or equal to the transmittance of the second conductive layer.

21. The display device of claim 20, wherein the first conductive layer includes a transparent conductive material, and the second conductive layer includes metal oxide.

22. The display device of claim 15, wherein the plurality of sub-pixels includes a first sub-pixel and a second sub-pixel, and
wherein the first sub-pixel emits any one of red, green, and blue light, and the second sub-pixel emits white light.

23. The display device of claim 22, wherein the first sub-pixel includes any one of a red color filter, a green color filter, and a blue color filter disposed on the second electrode.

24. The display device of claim 15, wherein the first electrode includes a first transparent conductive layer, a reflective layer disposed on the first transparent conductive layer, and a second transparent conductive layer disposed on the reflective layer.
